(19) United States
(12) Patent Application Publication
(10) Pub. No.: US 2026/0059749 A1
(43) Pub. Date: Feb. 26, 2026

(54) SEMICONDUCTOR MEMORY DEVICE AND METHOD FOR FABRICATING THE SAME

(71) Applicant: SK hynix Inc., Gyeonggi-do (KR)

(72) Inventors: Sungwon LIM, San Jose, CA (US); Tong ZHANG, San Jose, CA (US); Agus TJANDRA, San Jose, CA (US)

(21) Appl. No.: 18/814,594

(22) Filed: Aug. 26, 2024

(51) Int. Cl. H10B 43/27; H10B 41/27; H10B 41/35; H10B 43/35

(52) U.S. Cl. CPC H10B 43/27; H10B 41/27; H10B 41/35; H10B 43/35

(57) ABSTRACT

A semiconductor memory device including a structure of multiple cells and a method of fabricating multiple cells. The semiconductor memory device includes a pillar structure including a core hole and multiple pillar patterns surrounding the core hole and separated by the core hole, wherein each pillar pattern includes a stack of oxide and nitride layers alternatively stacked along a first direction, and includes a center pillar pattern at a center area, and corner pillar patterns at corner areas adjacent to the center area; a storage structure formed on an inner surface of a pocket area recessed into the center pillar pattern in a second direction; a channel layer formed on an inner surface of the storage structure; and a core insulating layer formed on an inner surface of the channel layer and the corner pillar patterns.

### BACKGROUND

### 1. Technical Field

The present disclosure relates to a semiconductor memory device, and more particularly to a three-dimensional semiconductor memory device.

### 2. Related Art

Semiconductor memory devices may include a plurality of memory cells capable of storing data. In order to improve a degree of integration of semiconductor memory devices, three-dimensional (3D) memory devices in which memory cells are arranged in three-dimensions on a substrate have been proposed.

In this context, embodiments of the present disclosure arise.

### SUMMARY

Embodiments of the present disclosure are directed to a semiconductor memory device including multiple cells and a method for fabricating the semiconductor memory device.

In accordance with one embodiment of the present disclosure, there is provided a semiconductor memory device. The semiconductor memory device includes a pillar structure including a core hole and multiple pillar patterns surrounding the core hole and separated by the core hole. Each pillar pattern includes a stack of oxide and nitride layers alternatively stacked along a first direction, and includes a center pillar pattern at a center area in a second direction, and corner pillar patterns at corner areas adjacent to the center area. The semiconductor memory device further includes a storage structure formed on an inner surface of a pocket area recessed into the center pillar pattern in the second direction, a channel layer formed on an inner surface of the storage structure, and a core insulating layer formed on an inner surface of the channel layer and the corner pillar patterns.

In accordance with another embodiment of the present disclosure, there is provided a method for manufacturing a semiconductor memory device. The method includes forming a pillar structure including a core hole and multiple pillar patterns surrounding the core hole and separated by the core hole. Each pillar pattern includes a stack of oxide and nitride layers alternatively stacked along a first direction, and includes a center pillar pattern at a center area in a second direction, and corner pillar patterns at corner areas adjacent to the center area. The method further includes forming a storage structure on an inner surface of a pocket area recessed into the center pillar pattern in the second direction, forming a channel layer on an inner surface of the storage structure, and forming a core insulating layer on an inner surface of the channel layer and the corner pillar patterns.

### BRIEF DESCRIPTION OF THE DRAWINGS

FIG. 1 is a block diagram illustrating a semiconductor memory device in accordance with one embodiment of the present disclosure.

FIG. 2 is a schematic circuit diagram illustrating a memory block of a semiconductor memory device in accordance with another embodiment of the present disclosure.

FIGS. 3A and 3B are views illustrating a structure of a semiconductor memory device in accordance with another embodiment of the present disclosure.

FIGS. 4A to 4C are schematic diagrams of multi-site cell structures of a semiconductor memory device in accordance with embodiments of the present disclosure.

FIGS. 5A to 5J are views illustrating a method for fabricating a semiconductor memory device including a recessed-type dual site cell structure in accordance with embodiments of the present disclosure.

FIGS. 6A to 6J and FIGS. 7A to 7J are cross-sectional views illustrating a semiconductor memory device including a recessed-type dual site cell structure in accordance with embodiments of the present disclosure.

FIGS. 8A to 8F are views illustrating a method for fabricating a semiconductor memory device including a recessed-type triple site cell structure in accordance with embodiments of the present disclosure.

FIGS. 9A to 9F and FIGS. 10A to 10F are cross-sectional views illustrating a semiconductor memory device including a recessed-type triple site cell structure in accordance with embodiments of the present disclosure.

FIG. 11 is a flowchart illustrating a method for fabricating a multi-site cell structure in accordance with embodiments of the present disclosure.

### DETAILED DESCRIPTION

The specific structural or functional descriptions disclosed herein are merely illustrative for the purpose of describing embodiments according to the concept of the present disclosure. The embodiments according to the concept of the present disclosure can be implemented in various forms, and should not be construed as limited to the embodiments set forth herein.

Embodiments of the present disclosure provide a semiconductor memory device capable of improving a degree of integration of memory cells.

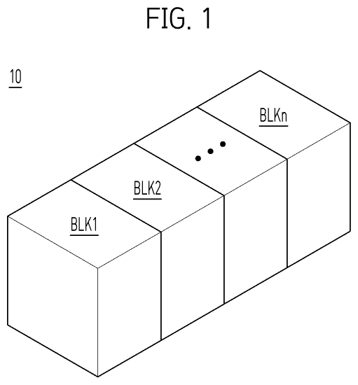

FIG. 1 is a block diagram illustrating a semiconductor memory device 10 in accordance with one embodiment of the present disclosure.

Referring to FIG. 1, the semiconductor memory device may include a plurality of memory blocks BLK1 to BLKn. The semiconductor memory device 10 may be a nonvolatile memory device such as a three-dimensional (3D) nonvolatile memory device or a two-dimensional (2D) nonvolatile memory device. In some embodiments, the nonvolatile memory device may be a NAND flash memory device.

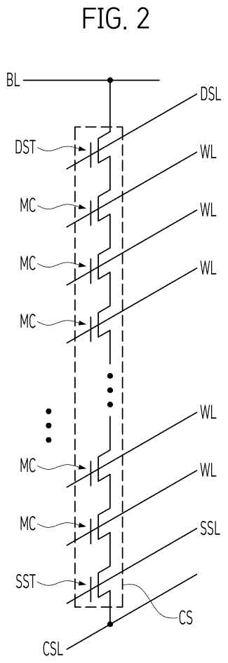

FIG. 2 is a schematic circuit diagram illustrating a memory block of a semiconductor memory device in accordance with another embodiment of the present disclosure.

Referring to FIG. 2, the memory block of the semiconductor memory device may include a memory cell string CS coupled to a bit line BL and a common source line CSL. Although a single memory cell string CS is illustrated, a plurality of memory cell strings may be coupled in parallel between the bit line BL and the common source line CSL.

The memory cell string CS may include a source select transistor SST, a plurality of memory cells MC, and a drain select transistor DST disposed between the common source line CSL and the bit line BL.

The source select transistor SST may control the electrical coupling between the plurality of memory cells MC and the common source line CSL. A single source select transistor SST may be disposed between the common source line CSL and the plurality of memory cells MC. Although not illustrated in the drawing, two or more source select transistors coupled in series to each other may be disposed between the common source line CSL and the plurality of memory cells MC. The source select transistor SST may be coupled to a source select line SSL. The operation of the source select transistor SST may be controlled by a source gate signal applied to the source select line SSL.

The plurality of memory cells MC may be disposed between the source select transistor SST and the drain select transistor DST. The memory cells MC between the source select transistor SST and the drain select transistor DST may be coupled in series to each other. The memory cells MC may be coupled to respective word lines WL. The operation of the memory cells MC may be controlled by cell gate signals applied to the word lines WL.

The drain select transistor DST may control the electrical coupling between the plurality of memory cells MC and the bit line BL. The drain select transistor DST may be coupled to a drain select line DSL. The operation of the drain select transistor DST may be controlled by a drain gate signal applied to the drain select line DSL.

Each of the memory cells MC may store single-bit data or multi-bit data.

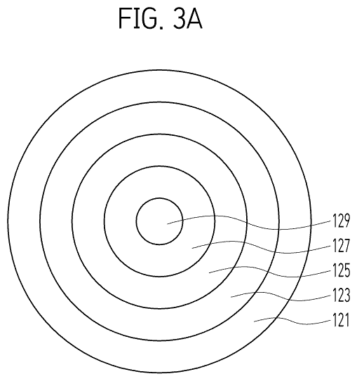

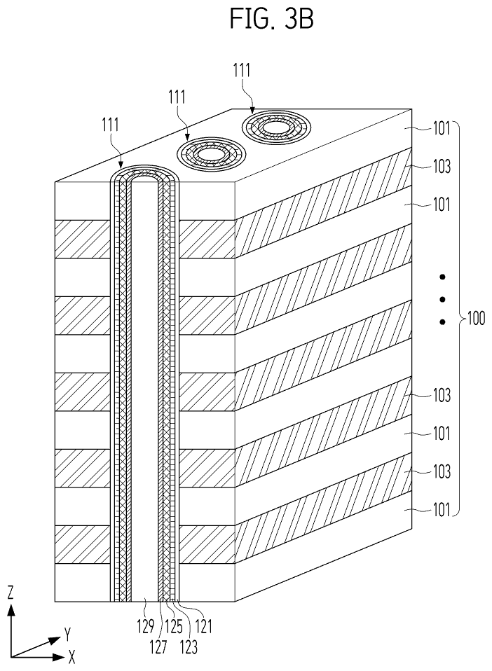

FIGS. 3A and 3B are views illustrating a structure of a semiconductor memory device in accordance with another embodiment of the present disclosure. FIG. 3A is a top view illustrating a memory cell of a semiconductor memory device, and FIG. 3B is a perspective view illustrating a semiconductor memory device (e.g., a 3D NAND flash memory device).

Referring to FIG. 3A and FIG. 3B, the semiconductor memory device may include a stacked body 100, a channel layer 127, a tunnel insulating layer 125, a data storage layer 123, and a blocking insulating layer 121.

The stacked body 100 may include interlayer insulating layers 101 and word lines 103. Each of the interlayer insulating layers 101 and the word lines 103 may be parallel to an X-Y plane. The interlayer insulating layers 101 and the word lines 103 may be stacked in a Z-axis direction perpendicular to the X-Y plane. The interlayer insulating layers 101 may be disposed alternately with the word lines 103.

The word lines 103 may be insulated from each other by the interlayer insulating layers 101. The word lines 103 may be used as the gate electrodes of the memory cells MC described with reference to FIG. 2. The interlayer insulating layers 101 may include an oxide layer (e.g., a silicon oxide layer). The word lines 103 may be initially a nitride layer (e.g., a metal nitride), but may be replaced by a doped semiconductor, metal, a metal nitride, and a metal silicide.

The stacked body 100 may be penetrated by a hole 111 extending in the Z-axis direction. The sidewalls of the interlayer insulating layers 101 may be defined along the sidewall of the hole 111. The sidewalls of the word lines 103 may be defined along the sidewall of the hole 111.

The channel layer 127 may include a semiconductor, such as silicon or the like. The channel layer 127 may extend in the Z-axis direction. The channel layer 127 may form the channel area of the memory cell string CS illustrated in FIG. 2, The channel layer 127 may be enclosed by the interlayer insulating layers 101 and the word lines 103.

The blocking insulating layer 121 may be interposed between the channel layer 127 and the stacked body 100. The blocking insulating layer 121 may include a single layer or a plurality of layers.

The data storage layer 123 may be interposed between the blocking insulating layer 121 and the channel layer 127. The data storage layer 123 may include a charge trap layer or a floating gate layer.

The tunnel insulating layer 125 may be interposed between the data storage layer 123 and the channel layer 127. The tunnel insulating layer 125 may include metal organic frameworks (MOF).

The semiconductor memory device may further include a core insulating layer 129 that fills the central area of the hole 111. The channel layer 127 may enclose the sidewall of the core insulating layer 129.

The channel layer 127, the tunnel insulating layer 125, the data storage layer 123, and the blocking insulating layer 121 may be formed in various structures.

In the illustrated example of FIGS. 3A and 3B, the blocking insulating layer 121, the data storage layer 123, and the tunnel insulating layer 125 may extend in the Z-axis direction along the sidewall of the channel layer 127. Each of the blocking insulating layer 121, the data storage layer 123, and the tunnel insulating layer 125 may be disposed between each of the word lines 103 and the channel layer 127, and may extend into space between each of the interlayer insulating layers 101 and the channel layer 127.

The blocking insulating layer 121 may include a silicon oxide layer, but embodiments of the present disclosure are not limited thereto. In one embodiment, the blocking insulating layer 121 may include a silicon oxide layer and a metal oxide layer between the silicon oxide layer and the stacked body 100. The metal oxide layer may include an oxide having higher dielectric constant than that of the silicon oxide layer. In another embodiment, the metal oxide layer may include an aluminum oxide layer.

The data storage layer 123 may include a charge trap layer extending in the Z-axis direction along the sidewall of the channel layer 127. In one embodiment, the charge trap layer may include a silicon nitride layer.

To increase the integration in 3D NAND memory device, various scaling schemes have been developed. For example, the scaling schemes include a logical scaling (e.g., a single-level cell (SLC), a multi-level cell (MLC), a triple-level cell (TLC), a quad-level cell (QLC), a penta-level cell (PLC)), a vertical scaling (e.g., 100 stacks (tiers), 200 stacks, 300 stacks, 400 stacks), a lateral scaling (e.g., 3 rows between a slit to a slit as one block, 9 rows, 19 rows, in which higher rows mean higher density), and a structural scaling (e.g., 4 dimension (4D), Periphery under Cell Array (PUA), Hybrid Wafer Bonding (HWB)).

However, these schemes reach their limits in terms of physical and cost. To overcome the limitations, additional physical scaling methods are being developed through the formation of multiple cells. For example, schemes of fabricating multiple cells based on the cutting of channel area are under consideration. For example, one cutting scheme of the channel area is described in U.S. Pat. No. 12,010,844B2 issued on Jun. 11, 2024, entitled “Semiconductor device and method of manufacturing the semiconductor device”, the entire contents of which are incorporated herein by reference. Since these schemes are based on the cutting of the channel area, sufficient channel area may not be provided. Accordingly, embodiments of the present disclosure provide a structure of multiple cells (i.e., multi-site or multi-slit cells (MSC)) and a method of fabricating multiple cells that can secure a sufficient channel area while having sufficient storage nodes and discrete cells by recessed pocket areas. The sufficient channel area means that the channel area is reduced due to channel separation. In some embodiments, the channel area can be adjusted to minimize the separation area or adjust the pillar CD size to allow sufficient channel area for enough channel current during the program, read, or erase operation. For example, the channel area may be around 50% of the channel area in the conventional cell. Although the storage node is separated and the area is reduced, the threshold voltage (Vt) window is sufficient to enable the logical scaling (MLC, TLC, QLC, or PLC). For example, the channel area may be around 50% of the storage node area in the conventional cell.

Embodiments of the present disclosure provides a scheme of fabricating an MSC structure by cutting a storage layer by recessed pocket formation with channel cutting through a sacrificial blocking layer in oval, triangular, and quadruple shapes. The conventional cell structure physically forms one cell per layer on one pillar. In accordance with the embodiments of the invention, the storage layer having the recessed pocket areas (i.e., the recessed pocket-type storage layer) is divided, separated and/or isolated by the sacrificial blocking layer. When the storage layer is separated and a channel layer is partially cut, each separated storage layer can act as an independent cell. Therefore, the embodiments of the invention can address the limitations of vertical scaling in current 3D NAND memory device.

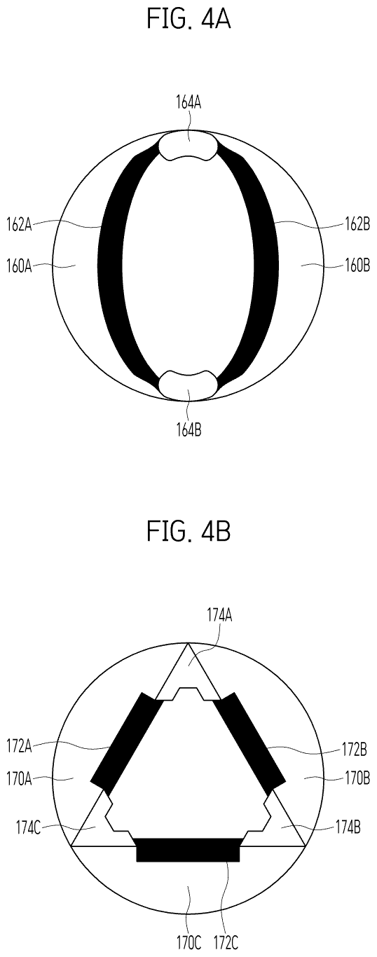

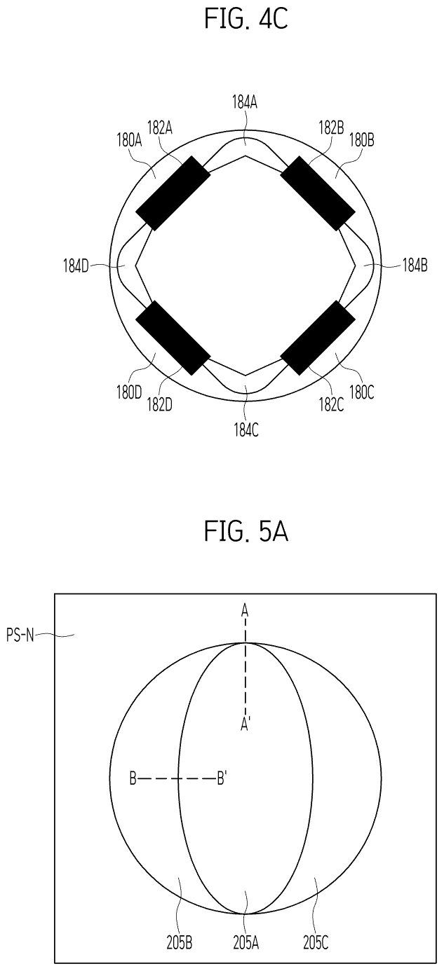

FIGS. 4A to 4C are schematic diagrams of multi-site cell structures of a semiconductor memory device in accordance with different embodiments of the present disclosure.

As shown in FIG. 4A, the multi-site cell structure may include a dual site (or slit) cell. As shown in FIG. 4B, the multi-site cell structure may include a triple site cell. As shown in FIG. 4C, the multi-site cell structure may include a quadruple site cell. Alternatively, the multi-site cell structure may include a pentagon site cell or a hexagon site cell.

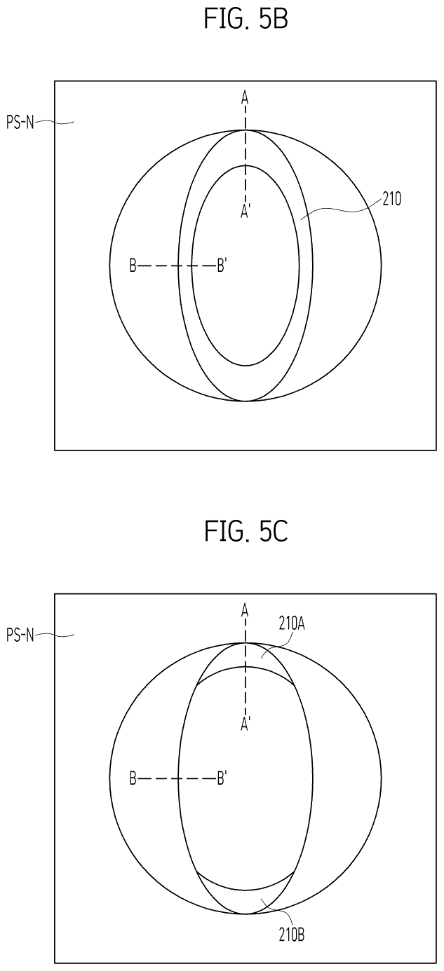

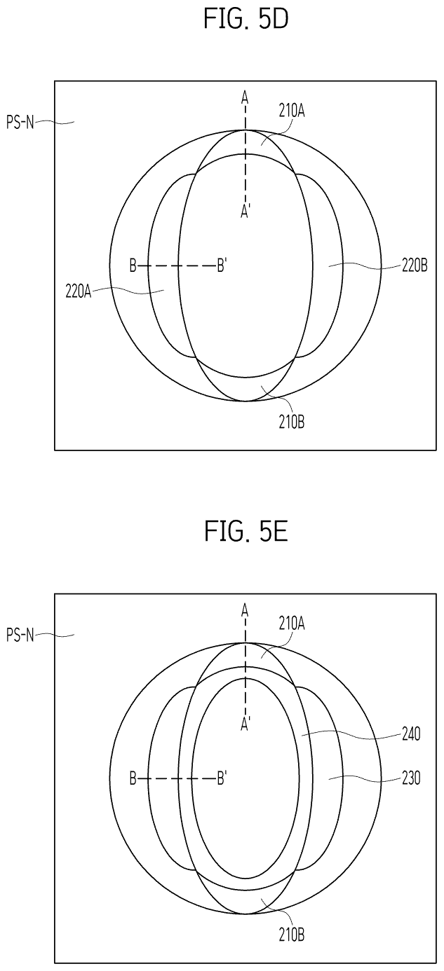

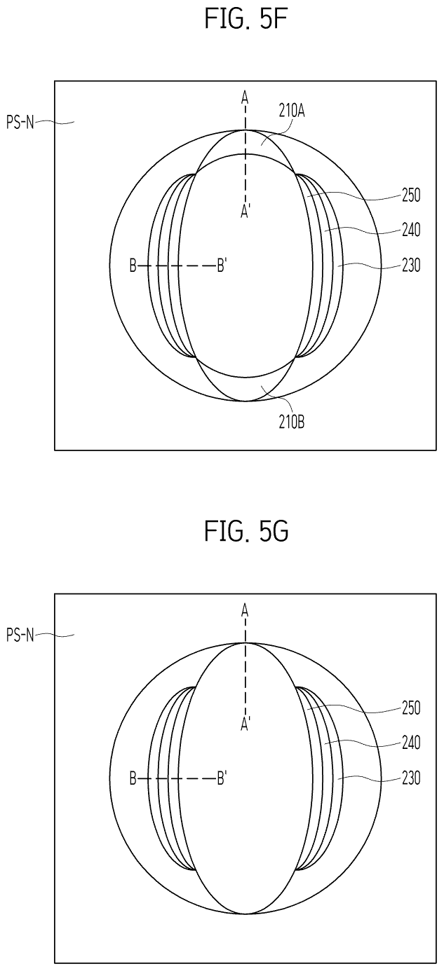

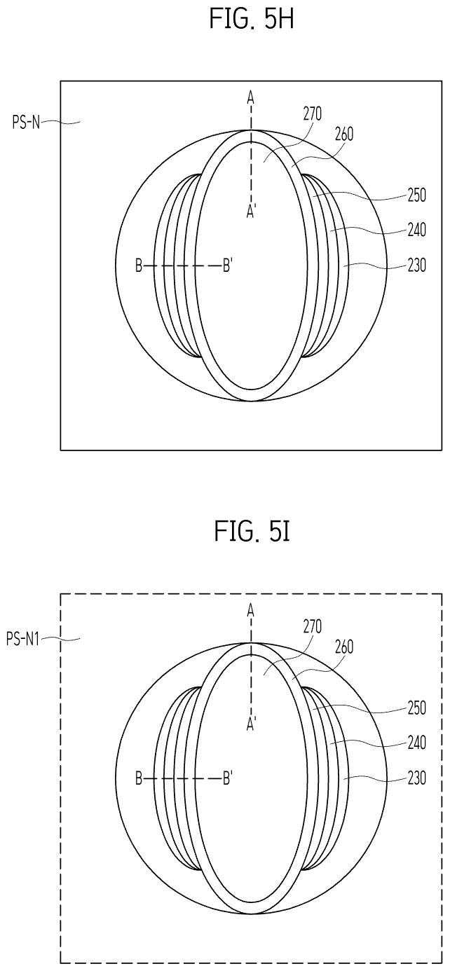

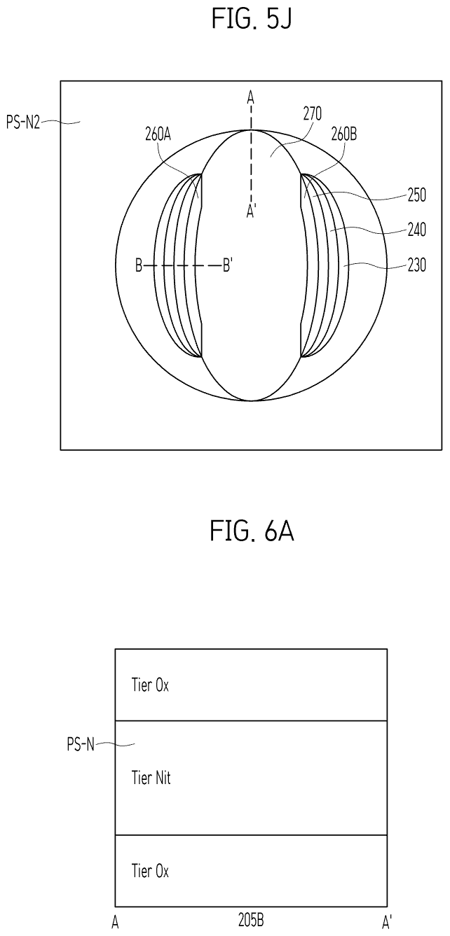

Referring to FIG. 4A, the dual site cell structure may include two cell patterns 160A, 160B. The cell patterns 160A, 160B may include two recessed storage patterns 162A, 162B, respectively. The recessed storage patterns 162A, 162B may have recessed pocket areas, which are separated by separation layers 164A, 164B. Each storage pattern can act as an independent cell. These elements and the process for forming the dual site cell structure are described with reference to FIGS. 5A to 7G.

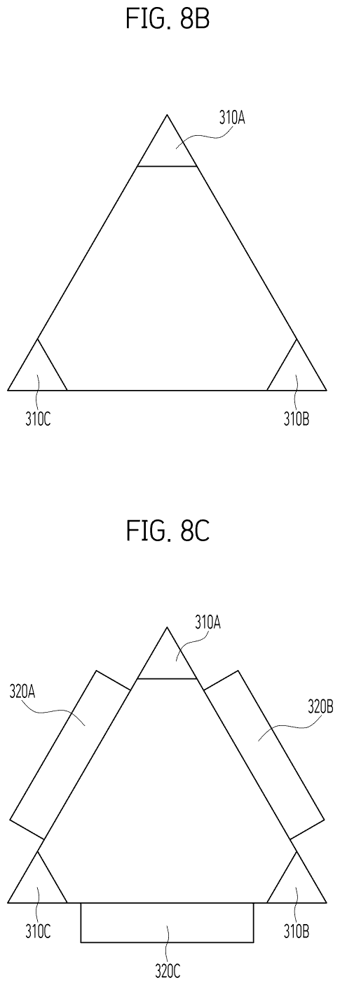

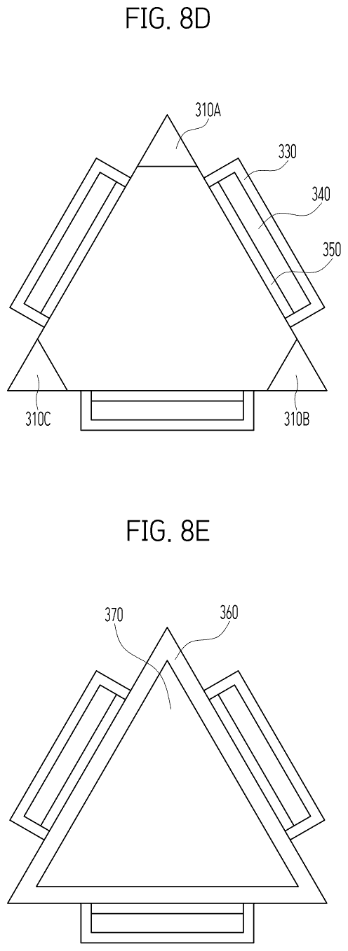

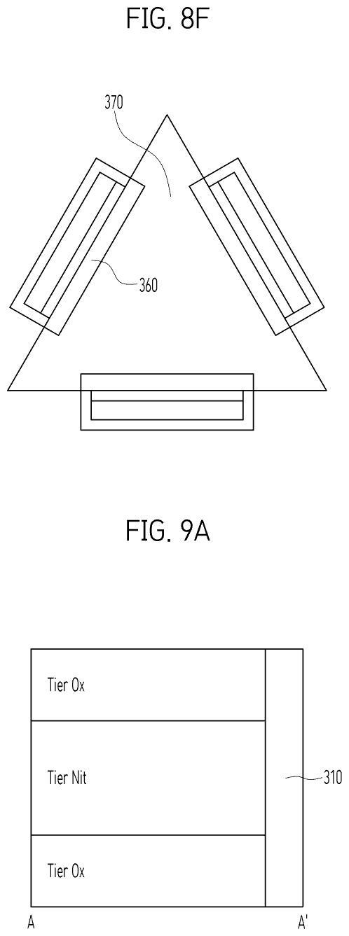

Referring to FIG. 4B, the triple site cell structure may include three cell patterns 170A, 170B, 170C. The cell patterns 170A, 170B, 170C may include three recessed storage patterns 172A, 172B, 172C, respectively. The recessed storage patterns 172A, 172B, 172C may have recessed pocket areas, which are separated by separation layers 174A, 174B, 174C. Each storage pattern can act as an independent cell. These elements and the process for forming the triple site cell structure are described with reference to FIGS. 8A to 10F.

Referring to FIG. 4C, the quadruple site cell structure may include four cell patterns 180A, 180B, 180C, 180D. The cell patterns 180A, 180B, 180C, 180D may include four recessed storage patterns 182A, 182B, 182C, 182D, respectively. The recessed storage patterns 182A, 182B, 182C, 182D may have recessed pocket areas, which are separated by separation layers 184A, 184B, 184C, 184D. Each storage pattern can act as an independent cell.

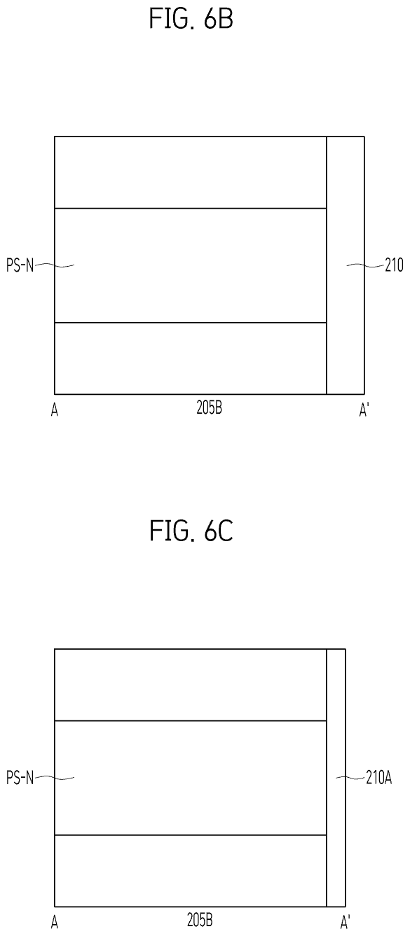

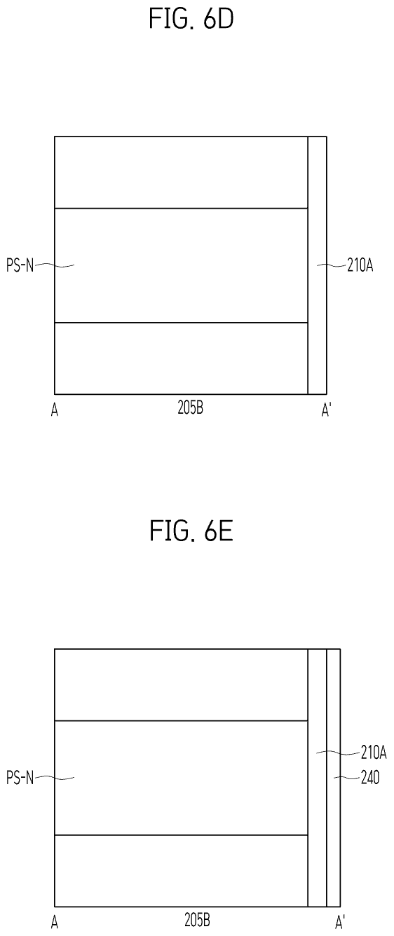

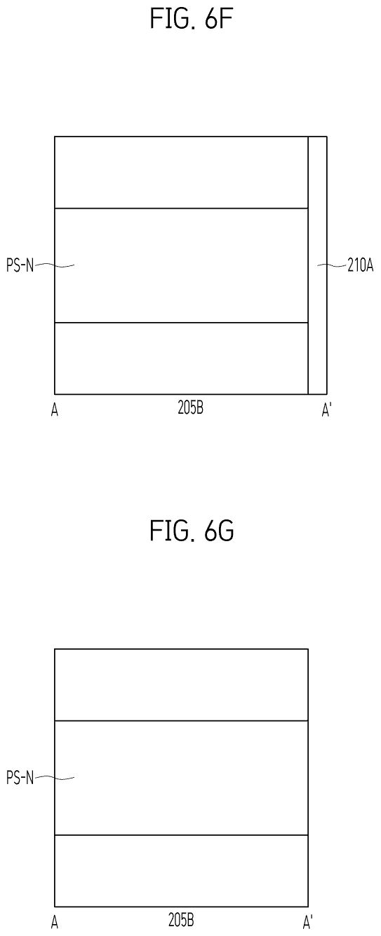

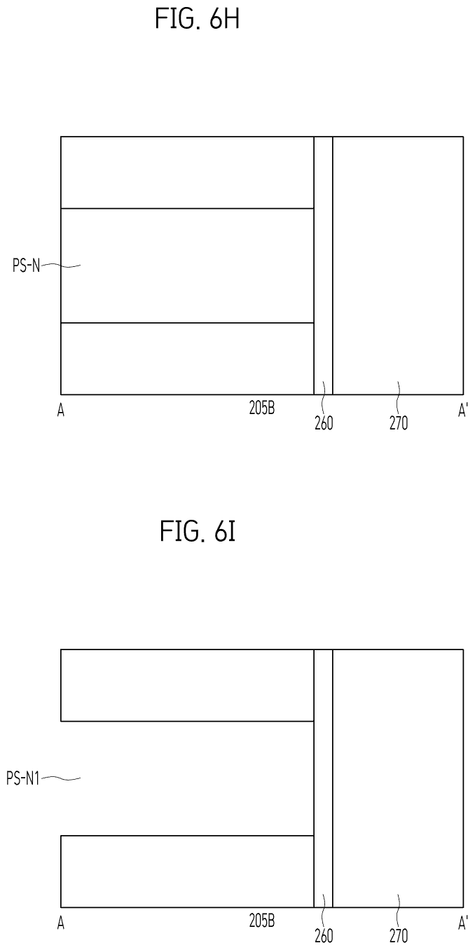

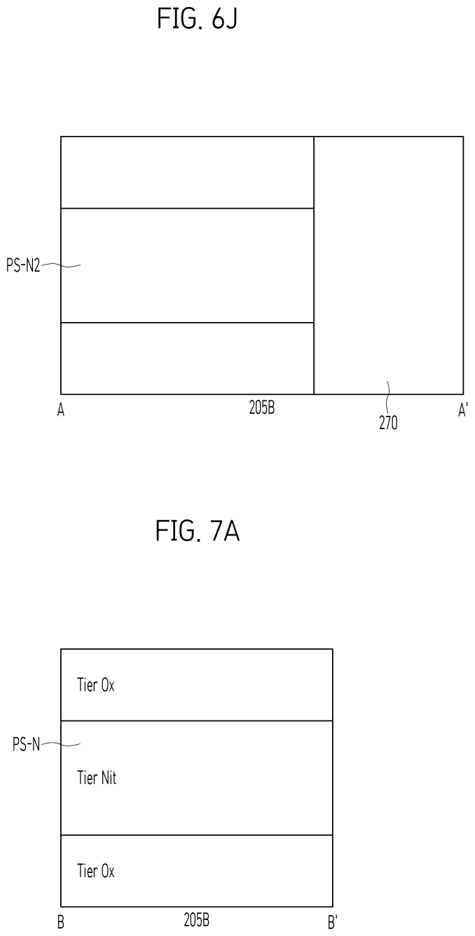

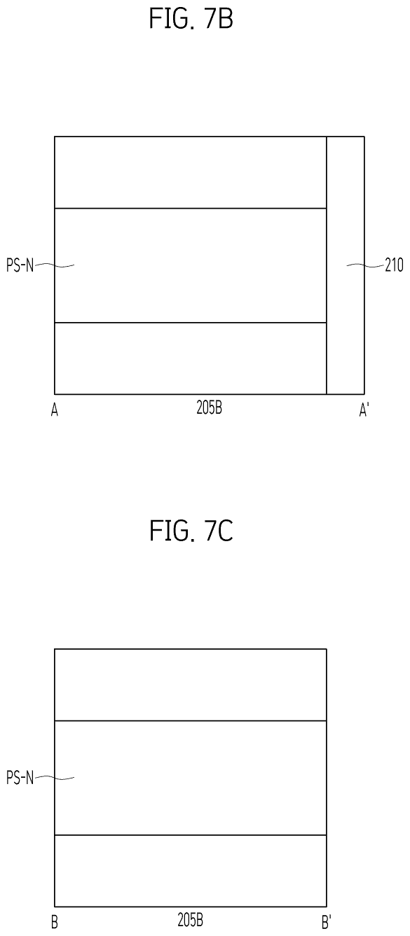

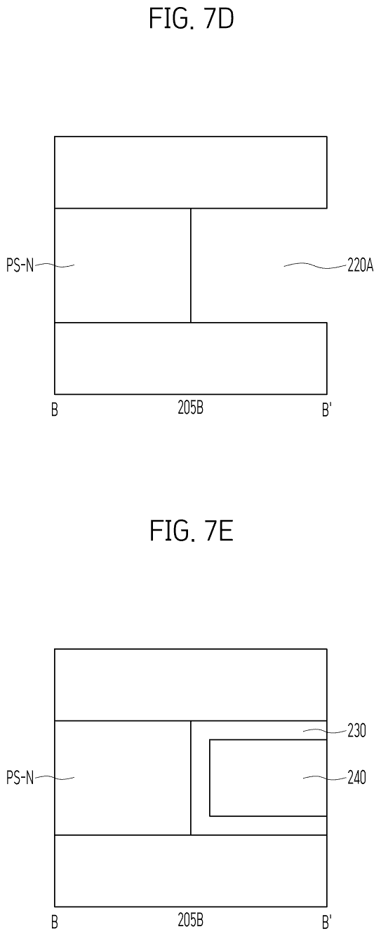

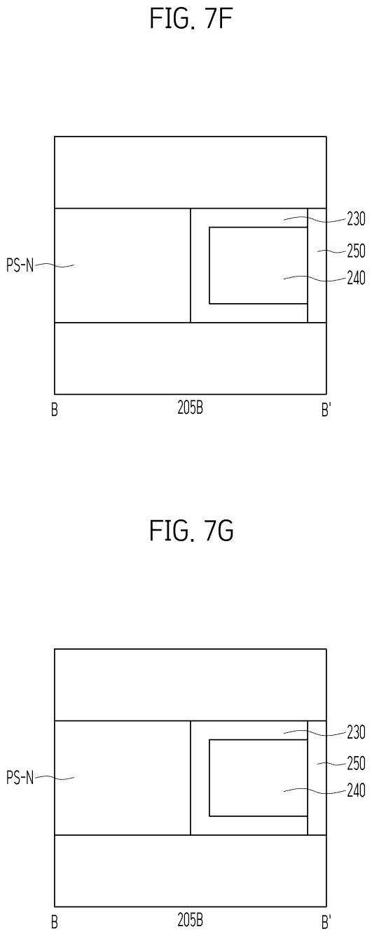

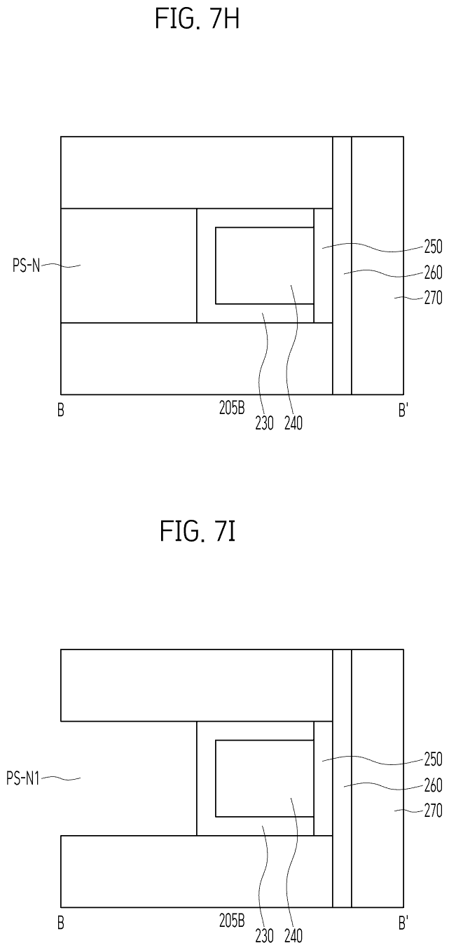

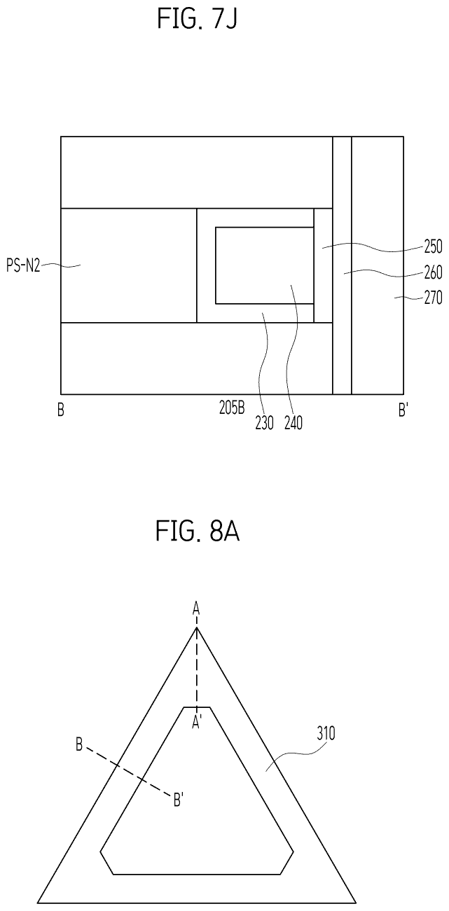

FIGS. 5A to 5J are views illustrating a method for fabricating a semiconductor memory device including a multi-site cell structure in accordance with embodiments of the present disclosure. FIGS. 6A to 6J and FIGS. 7A to 7J are cross-sectional views illustrating semiconductor memory device including a multi-site cell structure in accordance with embodiments of the present disclosure.

Referring to FIG. 5A, the semiconductor memory device may include a pillar structure PS-N, which includes a core hole 205A and multiple pillar patterns surrounding the core hole 205A and separated by the core hole 205A. In the illustrated example of FIG. 5A, the multiple pillar patterns may include two pillar patterns 205B, 205C. The core hole 205A may be formed by masking and etching a pillar including a stack of insulating layers 101 and conductive layers 103 alternatively stacked along a first direction (i.e., a vertical direction), as shown in FIG. 3B. That is, the resultant pillar structure PS-N may include the core hole 205A and the multiple pillar patterns 205B, 205C, and each pillar pattern may include a stack of insulating and conductive layers alternatively stacked along the first direction. In some embodiments, the stack of the insulating and conductive layers may include a structure of Oxide-Nitride (ON) tiers, as shown in FIGS. 6A and 7A. In some embodiments, each tier may be a stack of one oxide (insulator) and one nitride, which is replaced by metal to make metal word line. It is noted that FIGS. 6A to 6J and FIGS. 7A to 7J illustrate forming a semiconductor memory device on a pillar structure including ON tiers, while FIGS. 5A to 5J illustrate forming a semiconductor memory device on only nitride tier PS-N among the ON tiers.

An inner surface of each pillar pattern includes a center area, and corner areas (or pillar sidewall area) adjacent to the center area. The center area corresponds to an area taken along a dotted line B-B′ of FIG. 5A. One of the corner areas corresponds to an area taken along a dotted line A-A′ of FIG. 5A. The other of the corner areas corresponds to an area opposite to the area taken along the line A-A′. Each of the pillar patterns 205B, 205C may include a center pillar pattern at the center area, and corner pillar patterns at the corner areas.

In the illustrated example of FIG. 5A, the core hole 205A has an oval shape. In another example, the core hole 205A may have a triangular shape as shown in FIG. 8A. Alternatively, the core hole 205A may have a quadruple shape, a pentagonal shape, or a hexagonal shape.

Referring to FIGS. 5B, 6B and 7B, a sacrificial blocking layer 210 may be formed or deposited on an inner surface of the pillar patterns 205B, 205C. The sacrificial blocking layer 210 may have dry and wet etching selectivity with the pillar patterns 205B, 205C (i.e., ON or ONON stacks). In some embodiments, the sacrificial blocking layer 210 may include materials such as oxide, nitride, or undoped poly silicon (undoped-poly-Si), taking into account the ON stacks of the pillar patterns 205B, 205C. Due to the deposition characteristics, the sacrificial blocking layer 210 has a thicker thickness in a narrow area (i.e., corner areas) than that in the center area, as shown in FIGS. 5B, 6B and 7B. In some embodiments, the dry and wet etching selectivity of the sacrificial blocking layer 210 may be determined in consideration of the following: in the illustrated each corner area of FIG. 5B, the thickness of the sacrificial blocking layer 210 of the curved area (i.e., the corner area) is thicker than that of the less curved area (i.e., the center area), and the sacrificial blocking layer 210 can be removed using this difference in thickness, leaving the sacrificial blocking layer 210 only in the corner area through a dry or wet etching process, as shown in FIG. 5C. That is, as shown in FIG. 5B, the normal deposition method shows a lower sacrificial layer thickness of the less-curvature (center) area than in the curved (narrow) area. However, the tier oxide and tier nitride of the pillar patterns formed in the less curved area, in one embodiment, are maintained without loss and damage during the sacrificial etching process, as shown in FIG. 7C.

Referring to FIGS. 5C, 6C and 7C, the sacrificial blocking layer 210 may be separated into sacrificial blocking patterns 210A, 210B through a dry or wet etching process. In some embodiments, an isotropic etching method is used to separate the sacrificial blocking layer 210 using the deposition characteristics of the sacrificial blocking layer 210, which has a thicker thickness in the narrow area. As the result of the separation, the sacrificial blocking patterns 210A, 210B can remain only at the narrow areas (i.e., corner areas) of the oval shape, as shown in FIGS. 5C and 6C, and is removed at the center area of the pillar patterns 205B, 205C, as shown in FIGS. 5C and 7C.

Referring to FIGS. 5D, 6D and 7D, the tier nitride layer at the center area of the pillar pattern 205B may be selectively separated through an etching process using the sacrificial blocking patterns 210A, 210B as a barrier. In some embodiments, a part of the tier nitride layer at the center area of the pillar pattern 205B may be removed through a wet etching by a phosphoric acid (H₃PO₄). For example, the right side of the tier nitride layer in FIG. 7D may be removed. As a result, the recessed pocket areas 220A, 220B may be formed.

Referring to FIGS. 5E and 6E, after the forming of the recessed pocket areas 220A, 220B, the data storage layer 240 may be deposited on an inner surface of the sacrificial blocking patterns 210A at the corner area of the pillar pattern 205B.

Referring to FIGS. 5E and 7E, the blocking insulating layer 230 and the data storage layer 240 may be sequentially deposited on an inner surface of the recessed pocket area 220A formed at the center area of the pillar pattern 205B.

In some embodiments, the blocking insulating layer 230 may include a blocking oxide for electrical insulation from the word line (WL). The WL can be formed from one of conducting layers inside the pillar patterns 205B, 205C.

In some embodiments, the data storage layer 240 may be deposited on an inner surface of the sacrificial blocking patterns 210A or an inner surface of the blocking insulating layer 230. The data storage layer 240 may include a charge trap nitride that acts as a storage node. In some embodiments, the data storage layer 240 may include a single layer or multiple layers, each of which includes materials such as silicon nitride (Si₃N₄) and doped poly silicon (doped-poly-Si).

Referring to FIGS. 5F, 6F and 7F, the data storage layer 240 in areas other than the recessed pocket area 220A may be removed. For this removal, additionally oxidation and wet cleaning processes or dry etching may be performed to strip the data storage layer 240 in areas other than the recessed pocket area 220A. In some embodiments, the dry etching may have enough selectivity between tier oxide and nitride. As shown in FIG. 7F, the data storage layer 240 is separated or isolated into the recessed pocket area 220A. Each physically separated storage layer 240 can act as an individual cell, which corresponds to each of the storage patterns 162A, 162B as shown in FIG. 4A.

Referring to FIGS. 5F and 7F, a tunnel insulating layer 250 may be formed at the recessed pocket area 220A by oxidation of a part of the data storage layer 240. In the illustrated example of FIGS. 5F and 7F, the tunnel insulating layer 250 may be formed by oxidation of a sidewall (or pattern) of the data storage layer 240 at an edge area to be coupled to a channel layer 260 described below.

Referring to FIGS. 5G and 6G, the sacrificial blocking patterns 210A, 210B may be stripped at the corner area of the pillar pattern 205B. In some embodiments, the sacrificial blocking patterns 210A, 210B may be stripped by a wet cleaning.

As such, a storage structure may be formed on an inner surface of the center pillar pattern of each pillar pattern. At the center area, the pocket area 220A may be formed on an inner space of the center pillar pattern of each pillar pattern 205B, 205C. In the illustrated example of FIGS. 7D to 7G, the pocket area 220A may be formed on an inner space of a part of the center pillar pattern (i.e., a nitride tier PS-N of oxide-nitride (ON) tiers).

In some embodiments, the storage structure may be formed on the pocket area 220A recessed on a part of a nitride layer PS-N of the center pillar pattern. As shown in FIGS. 5G and 7G, the storage structure may include the blocking insulating layer 230 and the data storage layer 240, which are sequentially formed along an inner circumference of the pocket area 220A. Further, the storage structure may include the tunnel insulating layer 250 formed on the side (or edge) areas of the pocket area 220A.

Referring to FIGS. 5H and 7H, a channel layer 260 may be formed on an inner surface of the tunnel insulating layer 250 of the storage structure. Further, the channel layer 260 may be formed on an inner surface of oxide layers in the center pillar patten, which are adjacent to the nitride layer PS-N.

Referring to FIGS. 5H and 6H, the channel layer 260 may be formed on an inner surface of the tunnel insulating layer 250 of the storage structure, i.e., an inner space of the corner pillar patterns (i.e., oxide-nitride (ON) tiers). In some embodiments, the channel layer 260 may include a material such as poly silicon (poly-Si).

Referring to FIGS. 5H, 6H and 7H, a core insulating layer 270 may be formed on an inner surface of the channel layer 260. In some embodiments, the core insulating layer 270 may include a material such as an oxide to fill the remaining hole (i.e., gap) of the core hole 205A.

Referring to FIGS. 5I, 6I and 7I, a remaining part PS-N1 of the nitride layer PS-N may be exhumed or removed. The remaining part PS-N1 represents the nitride layer PS-N excluding the pocket area 220A.

Referring to FIGS. 5J, 6J and 7J, after the exhuming of the remaining part PS-N1 of the nitride layer PS-N, a selective oxidation process may be performed on the remaining part PS-N1. As a result, the remaining part PS-N1 may be oxidized to form an oxidation layer PS-N2. Thereafter, as shown in FIGS. 5J and 6J, the channel layer 260 deposited on the corner pillar patterns may be cut to form the channel layer patterns 260A, 260B shown in FIG. 5J at the center areas.

As such, at the center area (for example along B-B′ in FIG. 5A), the semiconductor memory device includes a center structure formed on an inner surface of a pillar structure. The center structure includes a storage structure, the channel layer pattern 260A/260B and the core insulating layer 270. The storage structure includes the blocking insulating layer 230, the data storage layer 240, and the tunnel insulating layer 250. The data storage layer 240 is formed to be isolated inside the recessed pocket area. At the corner area (for example along A-A′ in FIG. 5A), the semiconductor memory device includes a corner structure formed on an inner surface of the pillar structure. The corner structure includes the core insulating layer 270. That is, at the corner area, the storage structure is cut by the recessed pocket formation using a sacrificial blocking layer, and the channel layer is cut as well. Thus, storage structures at center areas including the isolated data storage layer 240 form recessed-type multi-site or multi-silt cells. Each of the storage structures corresponds to recessed storage patterns 162A, 162B of FIG. 4A. Each of the storage structures is isolated by the core insulating layer 270 at the corner areas, and by the cut in the channel layer 260 and the core insulating layer 270 at the center areas, which correspond to separation layers 164A, 164B of FIG. 4A.

As such, as the storage structure is separated and isolated and the channel layer at the corner areas is partially cut, each storage structure can act as an independent cell. Thus, embodiments of the present invention can dramatically overcome the limitations of vertical scaling in current 3D NAND. Further, embodiments of the present invention can secure sufficient storage nodes while improving string current, compared to the MSC structure based on the channel cutting scheme. In one example of an MSC channel cutting scheme, an MSC may be formed in a narrow curved area, In contrast, the embodiments of the present invention can provide an MSC formed in the less-curvature area in the opposite direction to the narrow curved area. The embodiments of the present invention can make the channel area relatively larger than the one example due to small separation area, which means that the string (channel) current can be improved.

As described above, FIGS. 5A to 7J illustrate a method for fabricating a semiconductor memory device including a multi-site cell structure including a dual site cell as shown in FIG. 4A.

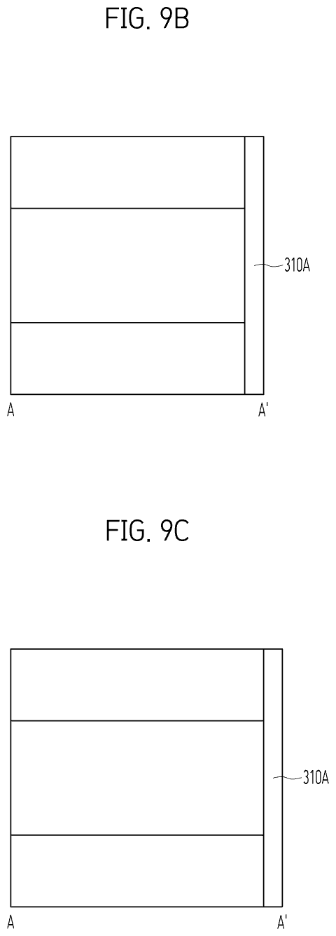

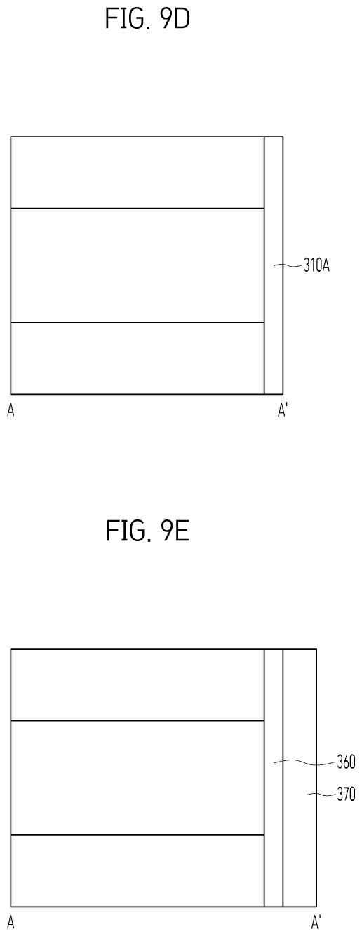

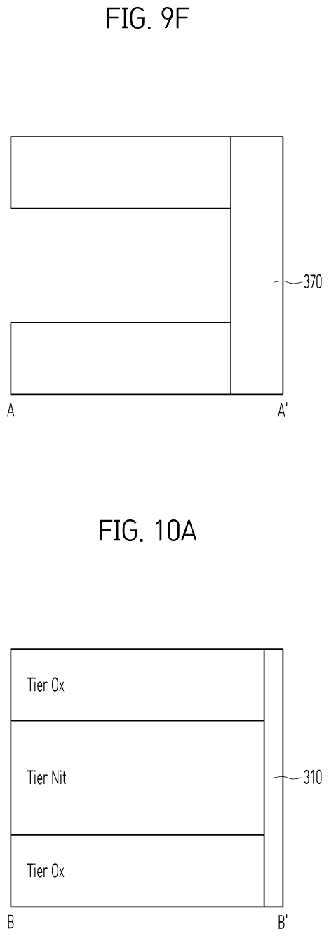

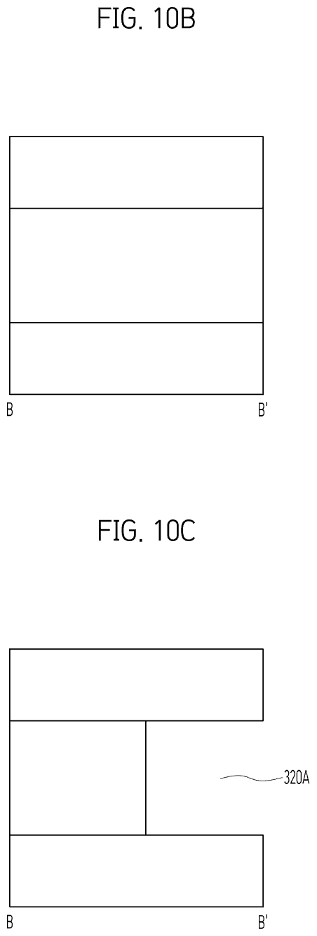

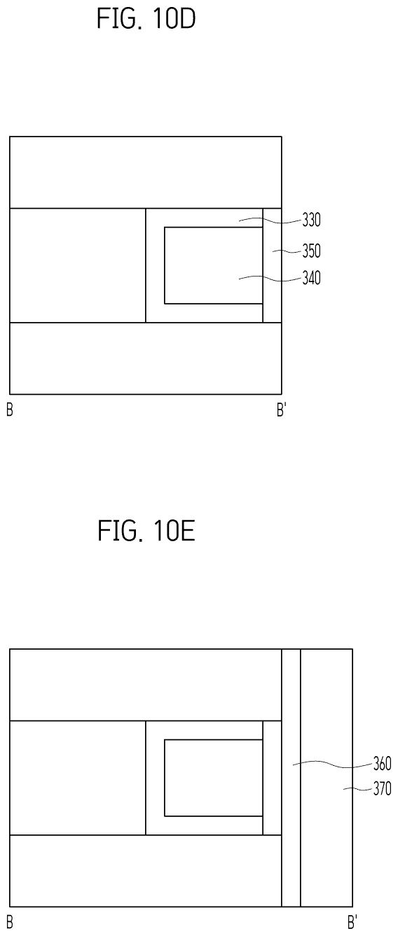

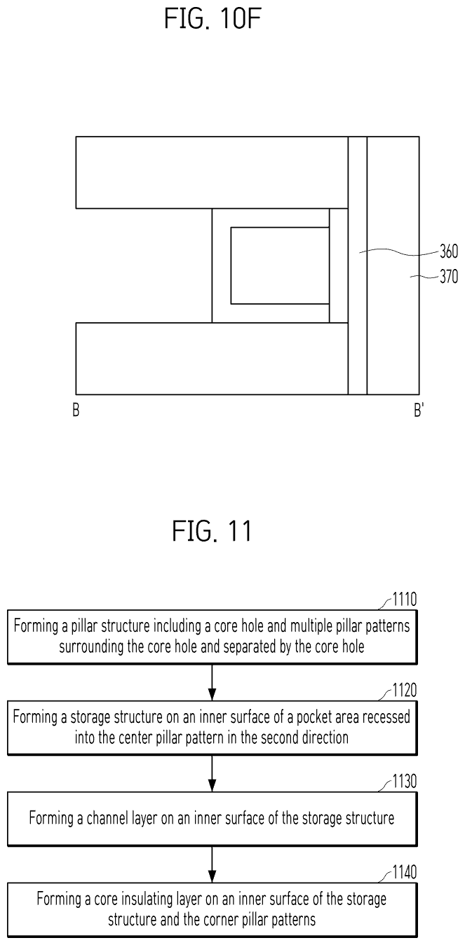

FIGS. 8A to 8F are views illustrating a method for fabricating a semiconductor memory device including a multi-site cell structure in accordance with embodiments of the present disclosure. FIGS. 9A to 9F and FIGS. 10A to 10F are cross-sectional views illustrating semiconductor memory device including a multi-site cell structure in accordance with embodiments of the present disclosure.

In accordance with the embodiment of FIGS. 8A to 10F, the semiconductor memory device may include a pillar structure, which includes a core hole and multiple pillar patterns surrounding the core hole and separated by the core hole. For example, the multiple pillar patterns may include three pillar patterns. The core hole may be formed by masking and etching a pillar including a stack of insulating layers 101 and conductive layers 103 alternatively stacked along a first direction (i.e., a vertical direction), as shown in FIG. 3B. That is, the resultant pillar structure may include the core hole and the multiple pillar patterns, and each pillar pattern may include a stack of insulating and conductive layers alternatively stacked along the first direction. In some embodiments, the stack of the insulating and conductive layers may include a structure of Oxide-Nitride (ON) tiers, as shown in FIGS. 6A and 7A. In some embodiments, each tier may be a stack of one oxide (insulator) and one nitride, which is replaced by metal to make metal word line. It is noted that FIGS. 9A to 9F and FIGS. 10A to 10F illustrate forming a semiconductor memory device on a pillar structure including ON tiers, while FIG. 8A to 8F illustrates forming a semiconductor memory device on only nitride tier among the ON tiers.

An inner surface of each pillar pattern includes a center area, and corner areas (or pillar sidewall area) adjacent to the center area. The center area corresponds to an area taken along a dotted line B-B′ of FIG. 8A. One of the corner areas corresponds to an area taken along a dotted line A-A′ of FIG. 8A. The other of the corner areas corresponds to an area opposite to the area taken along the line A-A′. Each of the pillar patterns may include a center pillar pattern at the center area, and corner pillar patterns at the corner areas.

For example, the core hole may have a triangular shape. Alternatively, the core hole may have a quadruple shape, a pentagonal shape, or a hexagonal shape.

Referring to FIGS. 8A, 9A and 10A, a sacrificial blocking layer 310 may be formed or deposited on an inner surface of the pillar patterns. The sacrificial blocking layer 310 may have dry and wet etching selectivity with the pillar patterns (i.e., ON or ONON stacks). In some embodiments, the sacrificial blocking layer 310 may include materials such as oxide, nitride, or undoped poly silicon (undoped-poly-Si), taking into account the ON stacks of the pillar patterns. Due to the deposition characteristics, the sacrificial blocking layer 310 has a thicker thickness in a narrow area (i.e., corner areas) than that in the center area, as shown in FIGS. 8A, 9A and 10A. In some embodiments, the dry and wet etching selectivity of the sacrificial blocking layer 310 may be determined in consideration of the following: in the illustrated each corner area of FIG. 8A, the thickness of the sacrificial blocking layer 310 of the curved area (i.e., the corner area) is thicker than that of the less curved area (i.e., the center area), and the sacrificial blocking layer 310 is removed using this difference in thickness, leaving the sacrificial blocking layer 310 only in the corner area through a dry or wet etching process, as shown in FIG. 8B. That is, as shown in FIG. 8A, the normal deposition method shows a lower sacrificial layer thickness of the less-curvature (center) area than in the curved (narrow) area. However, the tier oxide and tier nitride of the pillar patterns formed in the less curved area, in one embodiment, is maintained without loss and damage during the sacrificial etching process, as shown in FIG. 10B.

Referring to FIGS. 8B, 9B and 10B, the sacrificial blocking layer 310 may be separated into sacrificial blocking patterns 310A, 310B, 310C through a dry or wet etching process. In some embodiments, an isotropic etching method is used to separate the sacrificial blocking layer 310 using the deposition characteristics of the sacrificial blocking layer 310, which has a thicker thickness in the narrow area. As the result of the separation, the sacrificial blocking patterns 310A, 310B, 310C can remain only at the narrow areas (i.e., corner areas) of the triangular shape, as shown in FIGS. 8B and 9B, and is removed at the center area of the pillar patterns, as shown in FIGS. 8B and 10B.

Referring to FIGS. 8C, 9C and 10C, the tier nitride layer at the center area of the pillar pattern may be selectively separated through an etching using the sacrificial blocking patterns 310A, 310B, 310C as a barrier. In some embodiments, a part of the tier nitride layer at the center area of the pillar pattern may be removed through a wet etching by a phosphoric acid (H₃PO₄). For example, a right side of the tier nitride layer in FIG. 10C may be removed. As a result, the recessed pocket areas 320A, 320B, 320C may be formed.

After the forming of the recessed pocket areas 320A, 320B, 320C, the data storage layer 340 may be deposited on an inner surface of the sacrificial blocking patterns 310A at the corner area of the pillar pattern.

Referring to FIGS. 8D and 10D, the blocking insulating layer 330 and the data storage layer 340 may be sequentially deposited on an inner surface of the recessed pocket area 320A formed at the center area of the pillar pattern.

In some embodiments, the blocking insulating layer 330 may include a blocking oxide for electrical insulation from the word line (WL). The WL can be formed from one of conducting layers inside the pillar patterns.

In some embodiments, the data storage layer 340 may be deposited on an inner surface of the sacrificial blocking patterns 310A or an inner surface of the blocking insulating layer 330. The data storage layer 340 may include a charge trap nitride that acts as a storage node. In some embodiments, the data storage layer 340 may include a single layer or multiple layers, each of which includes materials such as silicon nitride (Si₃N₄) and doped poly silicon (doped-poly-Si).

Referring to FIGS. 8D, 9D and 10D, the data storage layer 340 in areas other than the recessed pocket area 320A may be removed. For this removal, additionally oxidation and wet cleaning processes or dry etching may be performed to strip the data storage layer 340 in areas other than the recessed pocket area 320A. In some embodiments, the dry etching may have enough selectivity between tier oxide and nitride. As shown in FIG. 10D, the data storage layer 340 is separated or isolated into the recessed pocket area 320A. Each physically separated storage layer 340 can act as an individual cell, which corresponds to each of the storage patterns 172A, 172B, 172C as shown in FIG. 4B.

Referring to FIGS. 8D and 10D, a tunnel insulating layer 350 may be formed at the recessed pocket area 320A by oxidation of a part of the data storage layer 340. In the illustrated example of FIGS. 8D and 10D, the tunnel insulating layer 350 may be formed by oxidation of a sidewall (or pattern) of the data storage layer 340 at an edge area to be coupled to channel layer 360 described below.

Referring to FIGS. 8E and 9E, the sacrificial blocking patterns 310A, 310B, 310C may be stripped at the corner area of the pillar pattern. In some embodiments, the sacrificial blocking patterns 310A, 310B, 310C may be stripped by a wet cleaning.

As such, a storage structure may be formed on an inner surface of the center pillar pattern of each pillar pattern. At the center area, the pocket area 320A may be formed on an inner space of the center pillar pattern of each pillar pattern. In the illustrated example of FIG. 10C, the pocket area 320A may be formed on an inner space of a part of the center pillar pattern (i.e., a nitride tier PS-N of oxide-nitride (ON) tiers).

In some embodiments, the storage structure may be formed on the pocket area 320A recessed on a part of a nitride layer or tier nitride (Tier Nit) of the center pillar pattern. As shown in FIGS. 8D and 10D, the storage structure may include the blocking insulating layer 330 and the data storage layer 340, which are sequentially formed along an inner circumference of the pocket area 320A. Further, the storage structure may include the tunnel insulating layer 350 formed on the side (or edge) areas of the pocket area 320A.

Referring to FIGS. 8E and 10E, a channel layer 360 may be formed on an inner surface of the tunnel insulating layer 350 of the storage structure. Further, the channel layer 360 may be formed on an inner surface of oxide layers in the center pillar patten, which are adjacent to the nitride layer.

Referring to FIGS. 8E and 9E, the channel layer 360 may be formed on an inner surface of the tunnel insulating layer 350 of the storage structure, i.e., an inner space of the corner pillar patterns (i.e., oxide-nitride (ON) tiers). In some embodiments, the channel layer 360 may include a material such as poly silicon (poly-Si).

Referring to FIGS. 8E, 9E and 10E, a core insulating layer 370 may be formed on an inner surface of the channel layer 360. In some embodiments, the core insulating layer 370 may include a material such as oxide to fill the remaining hole (i.e., gap) of the core hole.

Referring to FIGS. 8F, 9F and 10F, a remaining part of the nitride layer may be exhumed or removed. The remaining part represents the nitride layer excluding the pocket area 320A.

Referring to FIGS. 8F and 9F, after the exhuming of the remaining part of the nitride layer, a selective oxidation process may be performed on the remaining part. As a result, the remaining part may be oxidized to form an oxidation layer. Thereafter, the channel layer 360 deposited on the corner pillar patterns may be cut to form channel layer patterns at the center areas.

As such, at the center area, the semiconductor memory device includes a center structure formed on an inner surface of a pillar structure. The center structure includes a storage structure, the channel layer pattern and the core insulating layer 370. The storage structure includes the blocking insulating layer 330, the data storage layer 340, and the tunnel insulating layer 350. The data storage layer 340 is formed to be isolated inside the recessed pocket area. At the corner area, the semiconductor memory device includes a corner structure formed on an inner surface of the pillar structure. The corner structure includes the core insulating layer 370. That is, at the corner area, the storage structure is cut by the recessed pocket formation using a sacrificial blocking layer, and the channel layer is cut as well. Thus, storage structures at center areas including the isolated data storage layer 340 form recessed-type multi-site or multi-silt cells. Each of the storage structures corresponds to recessed storage patterns 172A, 172B, 172C of FIG. 4B. Each of the storage structures is isolated by the core insulating layer 370 at the corner areas, and by the channel layer 360 and the core insulating layer 370 at the center areas, which correspond to separation layers 174A, 174B, 174C of FIG. 4B.

As such, as the storage structure is separated and isolated and the channel layer is partially cut, each storage structure can act as an independent cell. Thus, embodiments of the present invention can dramatically overcome the limitations of vertical scaling in current 3D NAND. Further, embodiments of the present invention can secure sufficient storage nodes while improving string current, compared to the MSC structure based on the channel cutting scheme.

As described above, FIGS. 8A to 10F illustrate a method for fabricating a semiconductor memory device including a multi-site cell structure including a triangular site cell as shown in FIG. 4B. In the similar way, a multi-site cell structure including a quadruple site cell as shown in FIG. 4C can be fabricated.

FIG. 11 is a flowchart illustrating a method for fabricating a multi-site cell structure in accordance with embodiments of the present disclosure. As one example, FIG. 11 illustrates a method for fabricating a semiconductor memory device including a multi-site cell structure including a dual slit cell based on shown in FIG. 4A.

Referring to FIG. 11, the method may include forming (1110) a pillar structure including a core hole and multiple pillar patterns surrounding the core hole and separated by the core hole. In some embodiments, each pillar pattern includes a stack of tier oxide and nitride layers alternatively stacked along a first direction, and includes a center pillar pattern at a center area formed in a second direction (e.g., perpendicular to the first direction), and corner pillar patterns at corner areas adjacent to the center area.

The method may include forming (1120) a storage structure on an inner surface of the center pillar pattern (e.g. formed in the second direction).

The method may include forming (1130) a channel layer on an inner surface of the storage structure.

The method may include forming (1140) a core insulating layer on an inner surface of the storage structure and the corner pillar patterns.

In some embodiments, the method further includes: forming the pocket area in the second direction by removing a part of a nitride layer of the center pillar pattern in the second direction, and the forming of the storage structure includes forming the storage structure within the pocket area.

In some embodiments, the forming of the storage structure includes: forming a blocking layer along an inner circumference of the pocket area; forming a data storage layer on an inner surface of the blocking layer; and forming a tunnel insulating layer by oxidation of a sidewall of the data storage layer at an edge area coupling to the channel layer.

In some embodiments, the forming of the channel layer includes forming the channel layer on an inner surface of the tunnel insulating layer formed on an inner surface of the nitride layer in the center pillar pattern, and forming the channel layer on an inner surface of oxide layers in the center pillar patten, which are adjacent to the nitride layer.

In some embodiments, the method further includes: exhuming a remaining part of the nitride layer.

In some embodiments, the forming of the pocket area includes: depositing a sacrificial blocking layer over the inner surface of the pillar structure in the second direction; separating the sacrificial blocking layer such that the sacrificial blocking layer remains at the corner areas of the pillar structure and is removed at the center area of the pillar structure; and etching the part of the nitride layer of the center pillar pattern to form the pocket area.

In some embodiments, the sacrificial blocking layer is separated through a dry or wet etching.

In some embodiments, the dry or wet etching includes an isotropic etching such that the sacrificial blocking layer has a thicker thickness in the corner areas than a thickness of the center area.

In some embodiments, the sacrificial blocking layer includes an oxide, nitride, or undoped polysilicon layer.

In some embodiments, the forming of the pocket area includes etching the part of the nitride layer of the center pillar pattern through a wet etching using the separated sacrificial blocking layer as a barrier. The method further includes removing the sacrificial blocking layer at the corner areas of the corner pillar patterns after the part of the nitride layer of the center pillar pattern is etched.

Fabricating methods similar to the method shown in FIG. 11 may be performed for the semiconductor memory device including a triple (triangular) site cell shown in FIG. 4B, and a quadruple site cell shown in FIG. 4C.

As described above, embodiments of the present disclosure provide a semiconductor memory device including multiple cells (i.e., multi-site or multi-slit cells) and a method for fabricating the semiconductor memory device. By separating and isolating storage structures using a recessed pocket area and partially cutting a channel layer, each storage structure can act as an independent cell. Embodiments of the present invention can dramatically overcome the limitations of vertical scaling in current 3D NAND. Further, embodiments of the present invention can secure sufficient storage nodes while improving string current, compared to the MSC structure based on the channel cutting scheme.

While this patent document contains many specifics, these should not be construed as limitations on the scope of any invention or of what may be claimed, but rather as descriptions of features that may be specific to particular embodiments of particular inventions. Certain features that are described in this patent document in the context of separate embodiments can also be implemented in combination in a single embodiment.

Conversely, various features that are described in the context of a single embodiment can also be implemented in multiple embodiments separately or in any suitable subcombination. Moreover, although features may be described above as acting in certain combinations, one or more features from a combination can in some cases be excised from the combination, and the combination may be directed to a sub-combination or variation of a sub-combination.

Similarly, while operations are depicted in the drawings in a particular order, this should not be understood as requiring that such operations be performed in the particular order shown or in sequential order, or that all illustrated operations be performed, to achieve desirable results. Moreover, the separation of various system components in the embodiments described in this patent document should not be understood as requiring such separation in all embodiments.

Only a few implementations and examples are described and other implementations, enhancements and variations can be made based on what is described and illustrated in this patent document.

What is claimed is:

1. A semiconductor memory device comprising:
a pillar structure including a core hole and multiple pillar patterns surrounding the core hole and separated by the core hole, wherein each pillar pattern includes a stack of oxide and nitride layers alternatively stacked along a first direction, and includes a center pillar pattern at a center area in a second direction, and corner pillar patterns at corner areas adjacent to the center area;
a storage structure formed on an inner surface of a pocket area recessed into the center pillar pattern in the second direction;
a channel layer formed on an inner surface of the storage structure; and
a core insulating layer formed on an inner surface of the channel layer and the corner pillar patterns.

2. The semiconductor memory device of claim 1, wherein the pocket area is formed by removing a part of a nitride layer of the center pillar pattern in the second direction perpendicular to the first direction, and the storage structure is formed within the pocket area.

3. The semiconductor memory device of claim 2, wherein the storage structure includes:
a blocking layer formed along an inner circumference of the pocket area;
a data storage layer formed on an inner surface of the blocking layer; and
a tunnel insulating layer formed by oxidation of a sidewall of the data storage layer at an edge area to be coupled to the channel layer.

4. The semiconductor memory device of claim 3, wherein the channel layer is formed on an inner surface of the tunnel insulating layer formed on an inner surface of the nitride layer in the center pillar pattern, and the channel layer is further formed on an inner surface of oxide layers in the center pillar patten, which are adjacent to the nitride layer.

5. The semiconductor memory device of claim 4, wherein a remaining part of the nitride layer is removed from the center pillar pattern.

6. The semiconductor memory device of claim 2, wherein the pocket area is formed by:
depositing a sacrificial blocking layer over the inner surface of the pillar structure in the second direction;
separating the sacrificial blocking layer such that the sacrificial blocking layer remains at the corner areas of the pillar structure and is removed at the center area of the pillar structure; and
etching the part of the nitride layer of the center pillar pattern to form the pocket area.

7. The semiconductor memory device of claim 6, wherein the sacrificial blocking layer is separated through a dry or wet etching.

8. The semiconductor memory device of claim 7, wherein the dry or wet etching includes an isotropic etching of the sacrificial blocking layer which has a thicker thickness in the corner areas than a thickness of the center area.

9. The semiconductor memory device of claim 7, wherein the sacrificial blocking layer includes an oxide, nitride, or undoped polysilicon layer.

10. The semiconductor memory device of claim 6, wherein the part of the nitride layer of the center pillar pattern is etched to form the pocket area through a wet etching using the separated sacrificial blocking layer as a barrier, and
wherein, after the part of the nitride layer of the center pillar pattern is etched, the sacrificial blocking layer at the corner areas of the corner pillar patterns is removed.

11. A method for manufacturing a semiconductor memory device, the method comprising:
forming a pillar structure including a core hole and multiple pillar patterns surrounding the core hole and separated by the core hole, wherein each pillar pattern includes a stack of oxide and nitride layers alternatively stacked along a first direction, and includes a center pillar pattern at a center area in a second direction, and corner pillar patterns at corner areas adjacent to the center area;
forming a storage structure on an inner surface of a pocket area recessed into the center pillar pattern in the second direction;
forming a channel layer on an inner surface of the storage structure; and
forming a core insulating layer on an inner surface of the channel layer and the corner pillar patterns.

12. The method of claim 11, further comprising: forming the pocket area in the second direction perpendicular to the first direction by removing a part of a nitride layer of the center pillar pattern in the second direction,
wherein the forming of the storage structure includes forming the storage structure within the pocket area.

13. The method of claim 12, wherein the forming of the storage structure includes:
forming a blocking layer along an inner circumference of the pocket area;
forming a data storage layer on an inner surface of the blocking layer; and
forming a tunnel insulating layer by oxidation of a sidewall of the data storage layer at an edge area to be coupled to the channel layer.

14. The method of claim 13, wherein the forming of the channel layer includes forming the channel layer on an inner surface of the tunnel insulating layer formed on an inner surface of the nitride layer in the center pillar pattern, and forming the channel layer on an inner surface of oxide layers in the center pillar patten, which are adjacent to the nitride layer.

15. The method of claim 14, further comprising: removing a remaining part of the nitride layer in the center pillar pattern.

16. The method of claim 12, wherein the forming of the pocket area includes:
depositing a sacrificial blocking layer over the inner surface of the pillar structure in the second direction;
separating the sacrificial blocking layer such that the sacrificial blocking layer remains at the corner areas of the pillar structure and is removed at the center area of the pillar structure; and
etching the part of the nitride layer of the center pillar pattern to form the pocket area.

17. The method of claim 16, wherein the sacrificial blocking layer is separated through a dry or wet etching.

18. The method of claim 17, wherein the dry or wet etching includes an isotropic etching of the sacrificial blocking layer which has a thicker thickness in the corner areas than a thickness of the center area.

19. The method of claim 17, wherein the sacrificial blocking layer includes an oxide, nitride, or undoped polysilicon layer.

20. The method of claim 16, wherein the forming of the pocket area includes etching the part of the nitride layer of the center pillar pattern through a wet etching using the separated sacrificial blocking layer as a barrier, and
further comprising removing the sacrificial blocking layer at the corner areas of the corner pillar patterns after the part of the nitride layer of the center pillar pattern is etched.
